(19) United States
(12) Patent Application Publication
(10) Pub. No.: US 2024/0431063 A1
(43) Pub. Date: Dec. 26, 2024

(54) STORAGE APPARATUS

(71) Applicant: Hitachi, Ltd., Tokyo (JP)

(72) Inventors: Masahiro YAO, Tokyo (JP); Norio CHUJO, Tokyo (JP); Yutaka UEMATSU, Tokyo (JP); Masahiro TOYAMA, Tokyo (JP)

(21) Appl. No.: 18/595,202

(22) Filed: Mar. 4, 2024

(30) Foreign Application Priority Data
Jun. 22, 2023 (JP) 2023-102384

(51) Int. Cl. H05K 7/14; G06F 1/18; H05K 7/18

(52) U.S. Cl. CPC H05K 7/1452; G06F 1/187; H05K 7/183

(57) ABSTRACT

The storage apparatus includes a midplane provided vertically to an installation surface of the storage apparatus and provided with a plurality of connectors arranged in parallel in an X-axis direction parallel to the installation surface of the storage apparatus; and a plurality of adapters on each of which two drive apparatuses are mounted and which are arranged in parallel in the X-axis direction and connected to the midplane through the plurality of respective connectors in a Y-axis direction parallel to the installation surface and vertical to the X-axis direction. Each of the adapters includes a board including a plurality of connectors connected to respective connectors of the two drive apparatuses which are arranged in parallel in the Y-axis direction, in the Y-axis direction, and a frame for mounting the two drive apparatuses arranged in parallel in the Y-axis direction and the board to each of the adapters.

### BACKGROUND OF THE INVENTION

### 1. Field of the Invention

The present invention relates to a storage apparatus.

### 2. Description of the Related Art

Regarding storage apparatuses, the application of high-speed communication standards and a greater capacity inside the apparatus have been required. In particular, to achieve a greater capacity, it is necessary to increase the number of information storage apparatuses (hereinafter referred to as “drives”) mounted inside the storage housing.

However, since the storage housing is fixed to the rack and it is necessary to individually extract failed drives from the storage housing for replacement, a plurality of drives cannot be installed in the mounting and removing direction of the drive (the depth direction of the storage apparatus).

Thus, JP-2006-235964-A discloses a section for increasing the number of drives to be mounted, by adopting a board configured to allow a plurality of drives to be connected vertically to the depth direction of the storage apparatus.
Patent Literature 1: JP-2006-235964-A

### SUMMARY OF THE INVENTION

However, since the technology disclosed in JP-2006-235964-A described above employs a form in which the drives are connected vertically to the depth direction of the storage housing, in consideration of the dimensions in the connection direction of 2.5-inch drives and Enterprise and Datacenter Standard Form Factor (EDSFF) standard drives, the storage housing requires a housing height of 2.5 U (1 U is 1.75 inches=44.45 mm).

Meanwhile, a storage apparatus in which the drives are mounted and removed in the depth direction of the storage housing requires only a housing height of 2 U, in consideration of the dimensions in the vertical direction to the connection direction of 2.5-inch drives and EDSFF standard drives.

Further, since the rack is structured to mount storage apparatuses in 1 U units, when storage apparatuses with a height of 2.5 U are mounted on the rack, a space of 0.5 U inside the rack is wasted, which has been a problem.

Moreover, an integrated circuit (IC) of the storage housing is electrically connected to the drives with use of connectors, and as the number of connectors is increased in proportion to the number of drives, the signal quality is degraded due to reflection or crosstalk in the connectors, or transmission line losses. This makes high-speed transmission difficult, which has been a problem.

The present invention has been made in view of the circumstances described above and has an object to increase, in a storage apparatus, the number of drives to be mounted without wasting space, while minimizing the degradation of signal quality in the signal transmission lines to achieve high-speed transmission.

According to an aspect for solving the above-described problems, there is provided a storage apparatus including a plurality of drive apparatuses mounted, a midplane provided vertically to an installation surface of the storage apparatus and provided with a plurality of first connectors arranged in parallel in a first direction parallel to the installation surface of the storage apparatus, and a plurality of adapters on each of which a predetermined number of drive apparatuses among the plurality of drive apparatuses are mounted and which are arranged in parallel in the first direction and connected to the midplane through the plurality of respective first connectors in a second direction parallel to the installation surface and vertical to the first direction. Each of the adapters includes a board including a connector connection portion connected to a corresponding one of the first connectors in the second direction, and a plurality of second connectors electrically connected to the connector connection portion and connected to respective connectors of the predetermined number of drive apparatuses which are arranged in parallel in the second direction, in the second direction, and a frame for mounting the predetermined number of drive apparatuses arranged in parallel in the second direction and the board to each of the adapters.

According to the present invention, it is possible to increase, in the storage apparatus, the number of drives to be mounted without wasting space, while minimizing the degradation of signal quality in the signal transmission lines to achieve high-speed transmission.

### BRIEF DESCRIPTION OF THE DRAWINGS

FIG. 1 is a perspective view of a storage apparatus according to Embodiment 1;

FIG. 2 is a perspective view illustrating a state where drives are mounted on an adapter and a board according to Embodiment 1;

FIG. 3 is a perspective view illustrating a state where the drives are mounted on the adapter and the board according to Embodiment 1;

FIG. 4 is a perspective view of an adapter according to Embodiment 2;

FIG. 5 is a plan view of a board according to Embodiment 3;

FIG. 6 is a plan view illustrating a state where cooling air is flowing through the adapter according to Embodiment 1;

FIG. 7 is a plan view illustrating a state where cooling air is flowing through an adapter according to Embodiment 3;

FIG. 8 is a perspective view illustrating the interior of an adapter according to Embodiment 4;

FIG. 9 is a perspective view illustrating the adapter according to Embodiment 4;

FIG. 10 is a horizontal sectional view illustrating a state where drives are mounted on the adapter according to Embodiment 4;

FIG. 11 is a perspective view illustrating the interior of an adapter according to Embodiment 5;

FIG. 12 is a perspective view of the interior of an adapter according to Embodiment 6;

FIG. 13 is a perspective view of a board according to Embodiment 7;

FIG. 14 is a perspective view of a storage apparatus according to Embodiment 8; and

FIG. 15 is a perspective view of a board and an adapter according to Embodiment 9.

### DESCRIPTION OF THE PREFERRED EMBODIMENTS

Embodiments are described with reference to the drawings. Note that the embodiments described below do not limit the invention defined in claims, and all components and combinations thereof described in the embodiments are not always essential to the methods for solving the above-described problems of the invention.

In the following embodiments, when a plurality of components are described in a distinguished manner, the components are distinguished from each other by use of reference symbols with branch numbers, and when a plurality of components are described without distinction, the components are described without distinction by use of symbols without branch numbers. For example, when two connectors 11a and 11b are not distinguished from each other, the connectors 11a and 11b are described as “connector 11,” and when distinguished from each other, the connectors 11a and 11b are described as the “connector 11a and connector 11b.” A plurality of components described without distinction by use of symbols without branch numbers have similar configurations and functions.

### Embodiment 1

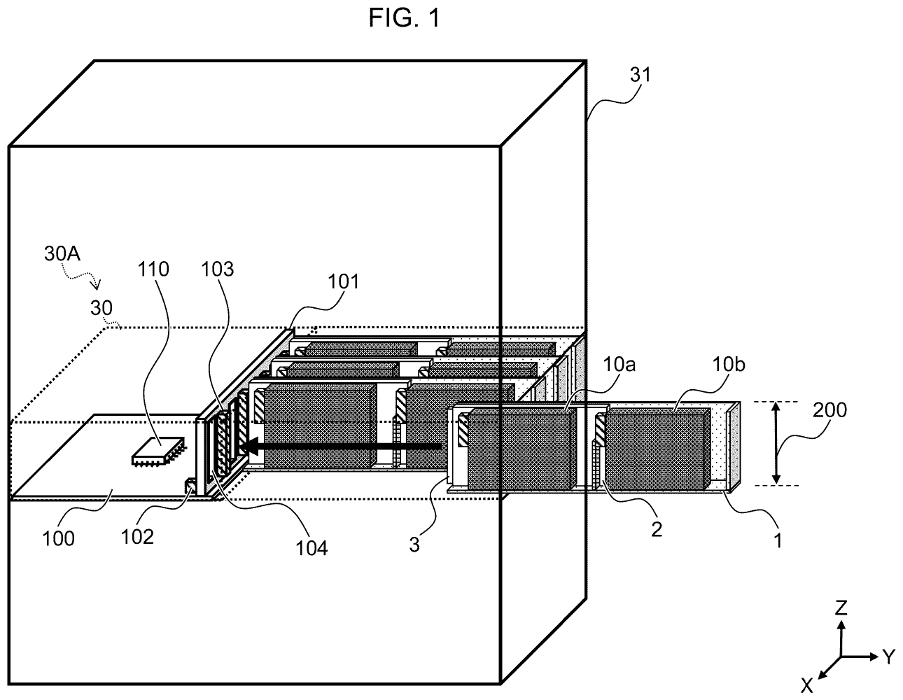

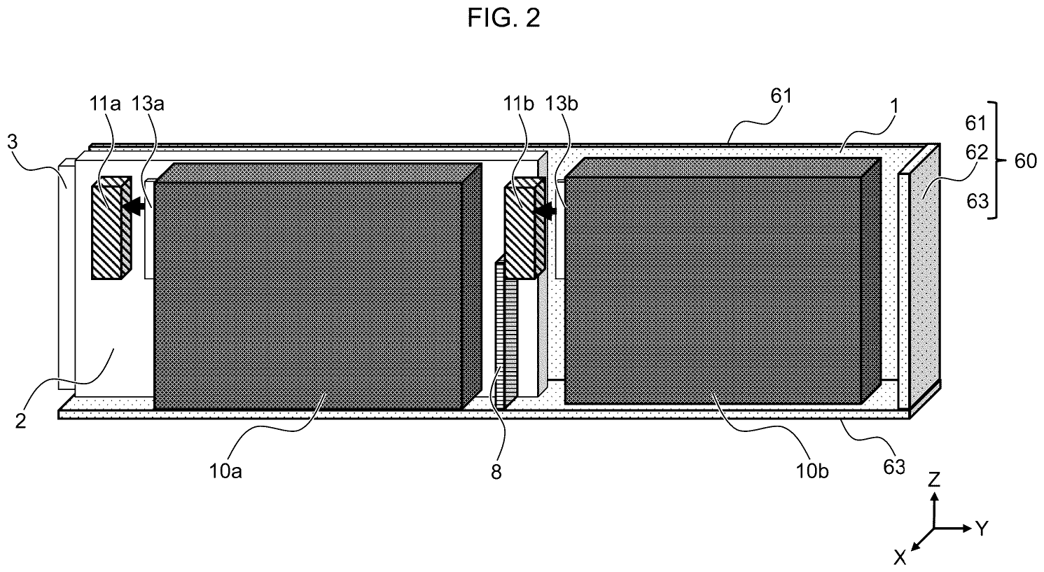

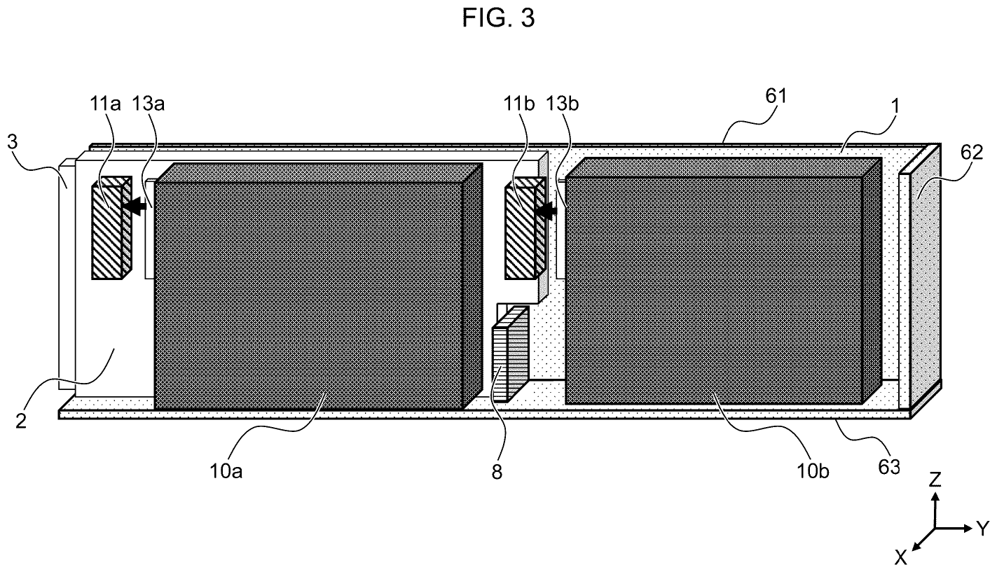

Embodiment 1 of the present invention is described with reference to FIG. 1, FIG. 2, and FIG. 3. FIG. 1 is a perspective view of a storage apparatus 30A according to Embodiment 1. FIG. 2 and FIG. 3 are perspective views illustrating a state where drive apparatuses 10 are mounted on an adapter 1 and a board 2 for drive extension according to Embodiment 1.

The storage apparatus 30A is installed with its installation surface being the surface parallel to the XY plane in the XYZ coordinate system having the X-axis, the Y-axis, and the Z-axis as its coordinate axes, as illustrated in FIG. 1.

The plurality of storage apparatuses 30A are mounted on a rack 31. The storage apparatus 30A includes a main board 100, a midplane 101, a plurality of connectors (first connectors) 103, and the plurality of adapters 1.

The main board 100 has mounted thereon an IC 110. The midplane 101 is connected to the main board 100 through a connector 102. Note that the midplane 101 may be connected to a storage controller (not illustrated) instead of the main board 100. The midplane 101 is installed vertically to the main board 100 and the installation surface. The plurality of connectors 103 are arranged in parallel in the X-axis direction (first direction), which is parallel to the installation surface of the storage apparatus 30A, on the midplane 101. Each of the plurality of adapters 1 includes the board 2 for drive extension having mounted thereon the two drive apparatuses 10.

The main board 100, the midplane 101, the connectors 102 and 103, and the IC 110 are accommodated in a housing 30 with a height of 2 U (in the positive direction of the Z-axis of FIG. 1). The midplane 101 has a through hole 104 for forming a flow path for cooling air provided therein.

The plurality of adapters 1 are arranged in parallel in the X-axis direction with respect to the midplane 101, as illustrated in FIG. 1. The plurality of adapters 1 are connected to the midplane 101 through the plurality of respective connectors 103 in the Y-axis direction (second direction) which is parallel to the installation surface of the storage apparatus 30A and vertical to the X-axis direction.

The plurality of adapters 1 each include the board 2 and a connection portion (connector connection portion) 3, as illustrated in FIG. 2. The connection portion 3 is connected to a corresponding one of the plurality of connectors 103 in the Y-axis direction. The board 2 includes two connectors (second connectors) 11a and 11b electrically connected to the connection portion 3 by the wiring inside the board 2 and connected to the respective connectors of the two drive apparatuses 10, which are arranged in parallel in the Y-axis direction, in the Y-axis direction.

In FIG. 2, the connector 11 is disposed such that the drive apparatus 10 can be mounted in the negative direction of the Y-axis and removed in the positive direction of the Y-axis. However, the arrangement method is not limited to this configuration, and, for example, the connector 11a and the connector 11b may be arranged side by side in the Z-axis direction to allow drive apparatuses 10a and 10b to be mounted and removed in the Y-axis direction. Further, the connection portion 3 may be a card edge or a connector.

The adapter 1 includes a frame 60 for mounting and fixing the two drive apparatuses 10a and 10b which are arranged in parallel in the Y-axis direction, and the board 2 to the adapter 1. The frame 60 is formed of at least one sheet of a material with rigidity, such as metal. In the present embodiment, the frame 60 has three surfaces, namely, a surface 61, a surface 62, and a surface 63, as illustrated in FIG. 2.

The frame 60 includes, for the adjacent drive apparatuses 10a and 10b arranged in parallel in the Y-axis direction, a stopper 8 between the drive apparatus 10a and the connector 11b connected to the drive apparatus 10b. The stopper 8 restricts the movement of the drive apparatus 10a in the Y-axis direction to prevent the drive apparatus 10a from coming into contact with the drive apparatus 10b.

In the adapter 1, the board 2 is fixed to the surface 61, and the stopper 8 is fixed to the surface 63. However, the configuration of the frame 60 provided to the adapter 1 is not limited to this example, and, for example, the frame 60 may be formed without the surface 62. Further, the placement location of the stopper 8 is not limited to this example, and, for example, as illustrated in FIG. 3, a notch for avoiding the stopper 8 may be provided in the board 2, and the stopper 8 may be disposed on the surface 61.

In FIG. 1, FIG. 2, and FIG. 3, the two drive apparatuses 10 are mounted on the adapter 1 as a predetermined number of drive apparatuses, but by providing the additional connectors 11 to the board 2, it is possible to mount the three or more drive apparatuses 10.

Since the drives can be mounted and removed in the Y-axis direction of FIG. 1, it is possible to reduce a height 200 of the adapter 1 to 2 U or less. Further, with the plurality of drive apparatuses 10 mounted in the Y-axis direction on the board 2, it is possible to increase the number of drives to be mounted, while reducing the height 200 of the adapter 1 to 2 U or less. Further, with the stopper 8, a structure that prevents the connector 11b and the drive apparatus 10b from receiving an impact when the drive apparatus 10a is mounted and removed can be implemented, which makes it possible to arrange the drive apparatuses 10 side by side in the Y-axis direction.

### Embodiment 2

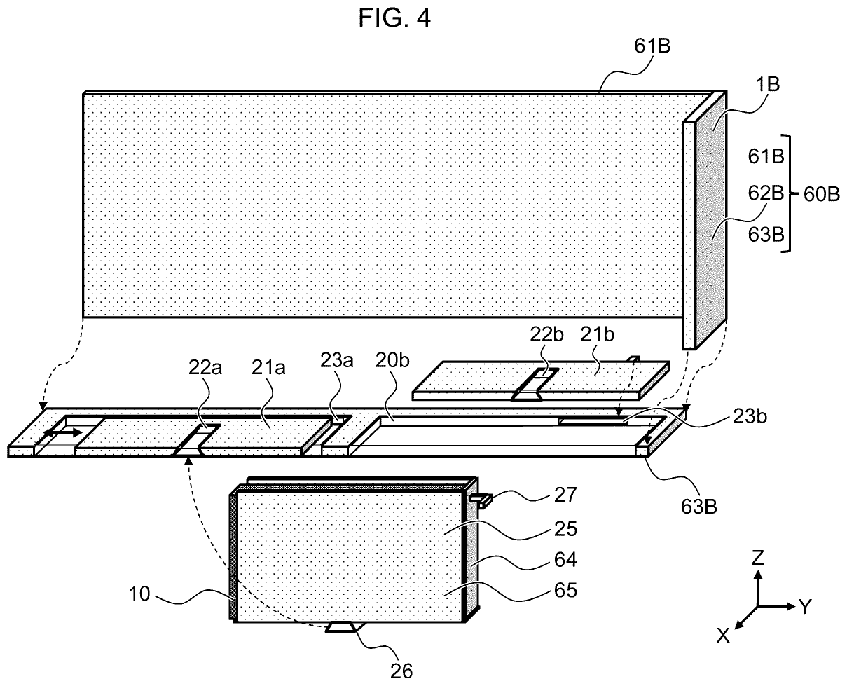

Embodiment 2 of the present invention is described with reference to FIG. 4. FIG. 4 is a perspective view of an adapter 1B according to Embodiment 2. Regarding points not specifically mentioned in the present embodiment, Embodiment 2 is similar to Embodiment 1.

The difference between the present embodiment and Embodiment 1 is that, as illustrated in FIG. 4, a slide rail 23 configured to allow the drive apparatus 10 to be moved in the Y-axis direction while being mounted on a frame 60B is provided in a surface 63B. The slide rail 23 is embedded in the surface 63B to allow a slide plate 21 having mounted thereon the drive apparatus 10 to slide in the Y-axis direction.

In FIG. 4, as a method of fixing the drive apparatus 10 to the slide plate 21, a fixing hole 22 is prepared in the slide plate 21, and a protrusion 26 provided on a drive adapter 25 having mounted thereon the drive apparatus 10 is fitted into the fixing hole 22. The present embodiment is not limited to this configuration, and, for example, the drive apparatus 10 may be directly fixed to the slide plate 21.

Further, as a method of sliding the slide plate 21, in FIG. 4, the slide rail 23, along which the slide plate 21 can slide without deviating from the slide rail 23, is embedded in the surface 63B. However, the present embodiment is not limited to this configuration, and, for example, the drive adapter 25 may be directly fixed to the slide rail 23. Further, the drive adapter 25 includes a handle 27 for sliding operation provided on a surface 64. The handle 27 is not limited in terms of placement and shape and may be provided on a surface 65, for example.

In this way, with the slide rail 23 provided in the adapter 1, the drive apparatus 10 is easily mounted and removed with the adapter 1 in use. Further, with the limited movement range of the slide rail 23, it is possible to mount and remove the drive apparatus 10a with respect to the connector 11a without applying an impact on the connector 11b and the drive apparatus 10b.

### Embodiment 3

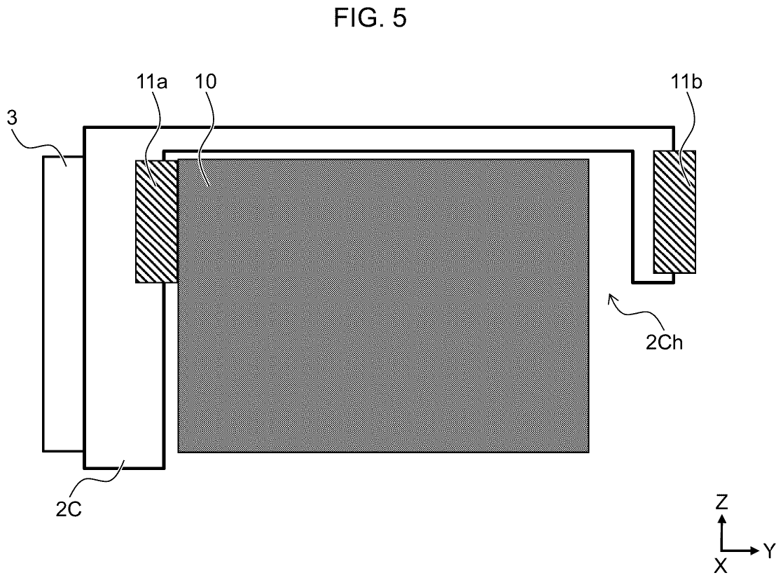

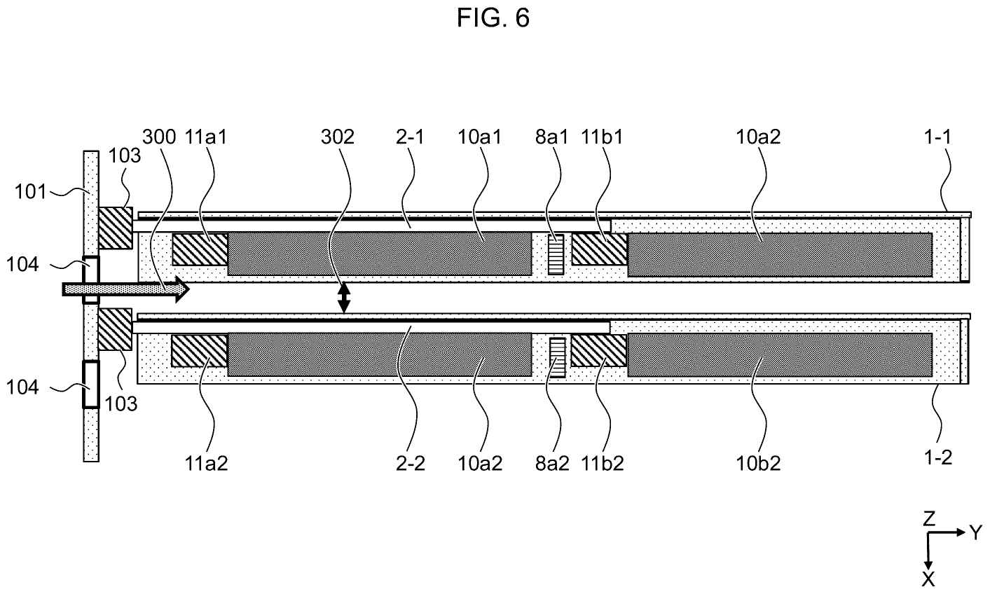

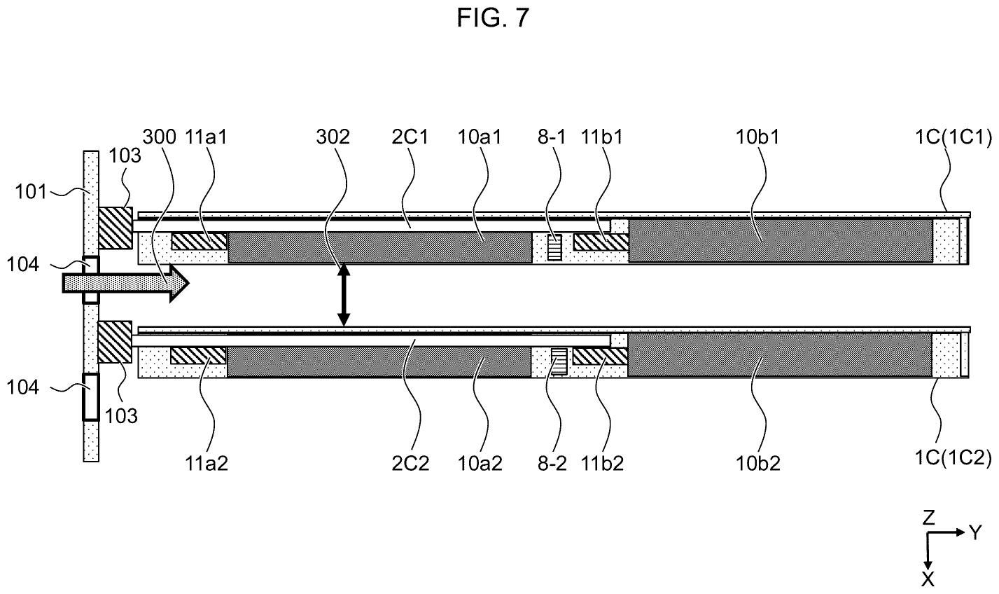

Embodiment 3 of the present invention is described with reference to FIG. 5, FIG. 6, and FIG. 7. FIG. 5 is a plan view of a board 2C according to Embodiment 3. FIG. 6 is a plan view illustrating a state where cooling air is flowing through the adapter 1 according to Embodiment 1. FIG. 7 is a plan view illustrating a state where cooling air is flowing through an adapter 1C according to Embodiment 3. Regarding points not specifically mentioned in the present embodiment, Embodiment 3 is similar to Embodiment 1.

FIG. 5 is a plan view of the board 2C when viewed from the positive direction of the X-axis. FIG. 6 is a plan view of a state where the adapter 1 is mounted on the midplane 101 in Embodiment 1 when viewed from the positive direction of the Z-axis. FIG. 7 is a plan view of a state where the adapter 1C is mounted on the midplane 101 in the present embodiment when viewed from the positive direction of the Z-axis.

The difference between the present embodiment and Embodiment 1 is that, as illustrated in FIG. 5, the board 2C has a notch portion 2Ch obtained by cutting out, from the connector 11a to the positive side in the Y-axis, a region corresponding to at least the sectional area parallel to the YZ plane of the drive apparatus 10. Instead of the notch portion 2Ch, the board 2C may be provided with an opening portion of a region corresponding to the sectional area parallel to the YZ plane of the drive apparatus 10.

In the present embodiment, as illustrated in FIG. 7, when viewed from the positive direction of the Z-axis, the thicknesses in the X-axis direction of drive apparatuses 10a1 and 10a2 connected to boards 2C1 and 2C2 adjacent to each other in the X-axis direction are overlapped with the thicknesses in the X-axis direction of the boards 2C1 and 2C2 in part. In other words, on the board 2C, both the surfaces in the X-axis direction of the drive apparatus 10a are exposed from the respective surfaces in the X-axis direction of the board 2C through the notch portion 2Ch or the opening portion, in a state where the connector of the drive apparatus 10a is connected to the connector 11.

Thus, the total thickness of the board 2C and the drive apparatuses 10a1 and 10a2 is reduced. With this, a distance 302 between adjacent adapters 1C1 and 1C2 is large compared to the distance between adapters 1-1 and 1-2 of Embodiment 1 illustrated in FIG. 6. Thus, the flow rate of cooling air 300 that passes between the adapters 1-1 and 1-2 through the through hole 104, which is formed between the adjacent connectors 103 and allows air to flow through the midplane 101, of the midplane 101 is increased. In this way, the drive apparatus 10 can be efficiently cooled, compared to Embodiment 1.

### Embodiment 4

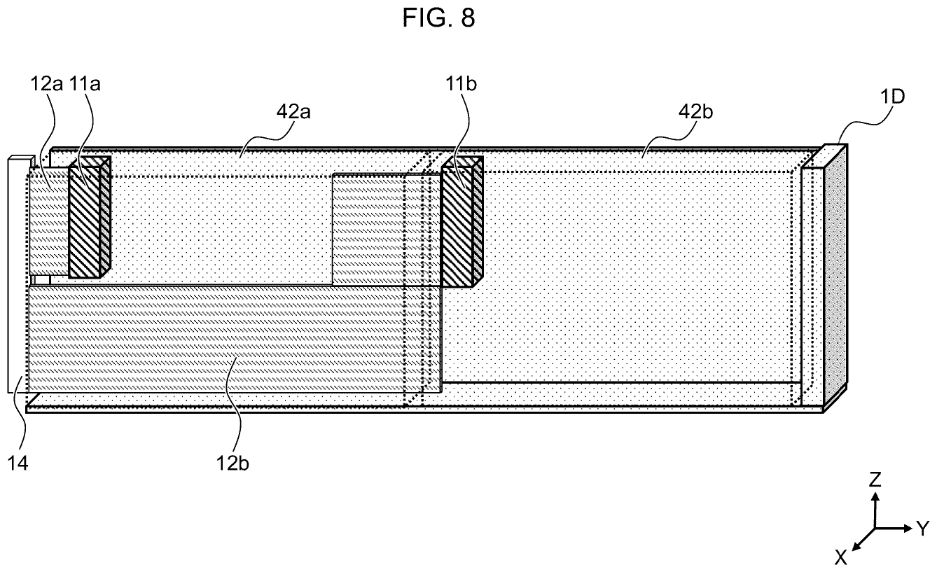

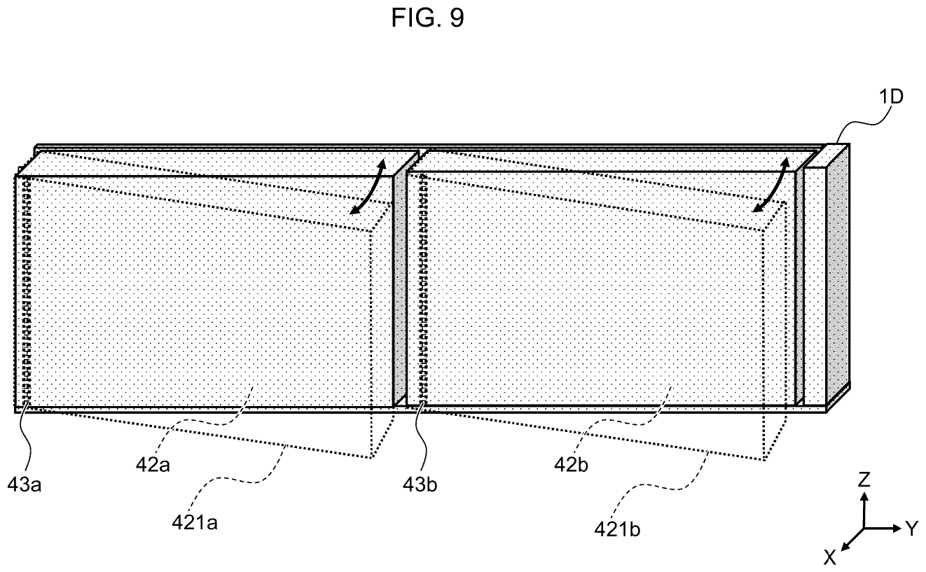

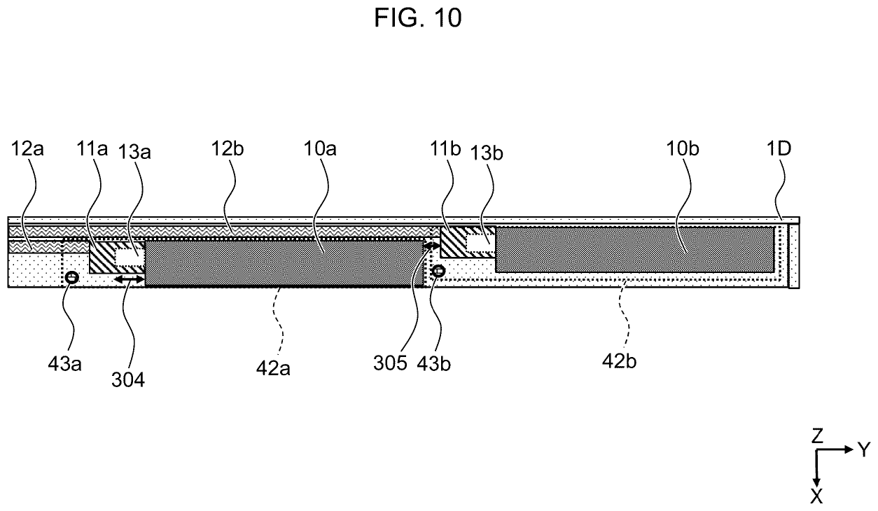

Embodiment 4 of the present invention is described with reference to FIG. 8, FIG. 9, and FIG. 10. FIG. 8 is a perspective view illustrating the interior of an adapter 1D according to Embodiment 4. FIG. 9 is a perspective view illustrating the adapter 1D according to Embodiment 4. FIG. 10 is a horizontal sectional view illustrating a state where the drive apparatus 10 is mounted on the adapter 1D according to Embodiment 4. Regarding points not specifically mentioned in the present embodiment, Embodiment 4 is similar to Embodiment 1.

The difference between the present embodiment and Embodiment 1 lies in two points, as illustrated in FIG. 8. The first point is that a cable 12 including a connection portion (connector connection portion) 14 is used for signal transmission inside the adapter 1D, instead of the board 2. The second point is that a drive mounting portion 42 is provided to the adapter 1D, as illustrated in FIG. 9. Drive mounting portions 42a and 42b are provided with the connectors 11a and 11b, respectively, and are connected to cables 12a and 12b. The drive mounting portions 42a and 42b each include a frame 421a or 421b for mounting and fixing the drive apparatus 10, and a rotation axis 43.

In the present embodiment, as illustrated in FIG. 9, the drive mounting portion 42 rotates about the rotation axis 43 from the Y-axis direction to the X-axis direction along the arrow, thereby allowing the drive apparatus 10 to be mounted and removed from the X-axis direction or an oblique direction at a predetermined angle with respect to the Y-axis (an angular direction between the angle formed by the X-axis and the Y-axis). That is, the drive mounting portion 42 rotates about the rotation axis in the Z-axis direction (third direction) vertical to the X-axis direction and the Y-axis direction in the adapter 1D, thereby allowing the drive apparatus 10 to be mounted and removed with respect to the drive mounting portion 42 from a direction different from the Y-axis direction. With this, the drive apparatus 10 is easily mounted.

Further, as illustrated in FIG. 10, it is possible to make a space 305 between the drive apparatus 10a and the connector 11b narrower than a width 304 in the Y-axis direction of a connection portion 13a required for the removal of the drive apparatus 10a in the positive direction of the Y-axis. Thus, compared to Embodiments 1 to 3, the lengths in the Y-axis direction of the adapters 1, 1B, and 1C can be shortened, for example, so that the drive apparatus 10 can be efficiently disposed. To obtain this effect, instead of using the cable 12, a board that has a flexible portion at least near the connector 11 may be used. Moreover, since the transmission loss of cables is smaller than that of board wiring, by using the cable, it is possible to prevent the deterioration of signal quality.

### Embodiment 5

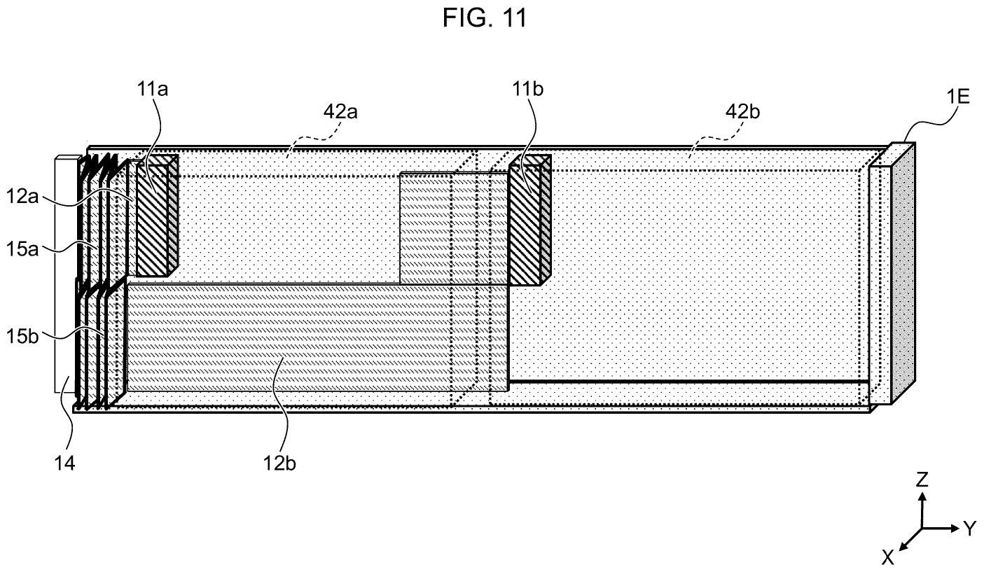

Embodiment 5 of the present invention is described with reference to FIG. 11. FIG. 11 is a perspective view illustrating the interior of an adapter 1E according to Embodiment 5. Regarding points not specifically mentioned in the present embodiment, Embodiment 5 is similar to Embodiment 4.

The difference between the present embodiment and Embodiment 4 is that the connection portion 14 connected to the connector 103 of the midplane 101 is connected to the connector 11 inside a drive mounting portion 42a by a bellows cable 15 with a folded portion folded in a bellows shape. Bellows cables 15a and 15b are connected to the cables 12a and 12b, respectively.

In the present embodiment, when the adapter 1E is pulled out from the rack 31, the bellows of the bellows cable 15 extends, thereby making it possible to replace the drive apparatuses 10 one by one while maintaining electrical connection between the drive apparatus 10 and the connector 103 as much as possible.

### Embodiment 6

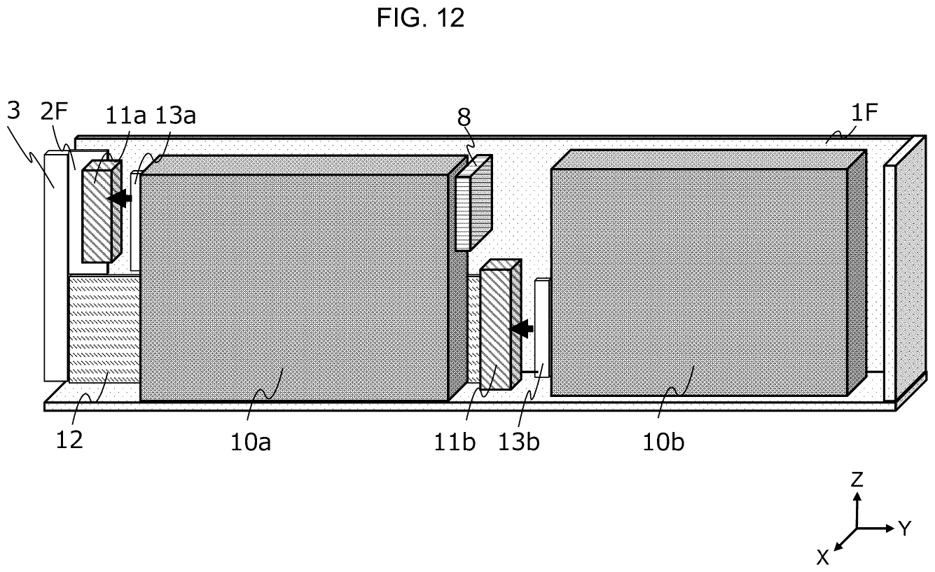

Embodiment 6 of the present invention is described with reference to FIG. 12. FIG. 12 is a perspective view of the interior of an adapter 1F according to Embodiment 6. Regarding points not specifically mentioned in the present embodiment, Embodiment 6 is similar to Embodiment 4.

The difference between the present embodiment and Embodiment 4 is that the cable 12 is used only for the connector 11b with a long transmission distance from the IC 110, and for the connector 11a with a short transmission distance, a board 2F is used for signal transmission, instead of the cable.

In the present embodiment, a cable is used only for the connection of the drive apparatus 10 that is at a distance equal to or greater than a certain distance from the IC 110 and is thus affected significantly by the degradation of signal quality. Meanwhile, for the connection of the drive apparatus 10 close to the IC 110, an inexpensive board is used. With this, there is an effect that the degradation of signal quality can be prevented more effectively in terms of cost than Embodiment 4.

### Embodiment 7

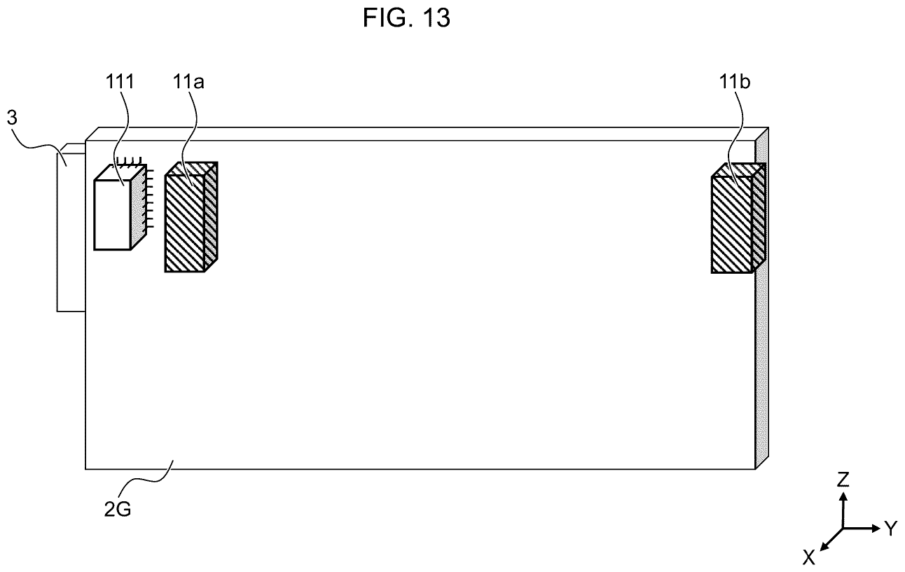

Embodiment 7 of the present invention is described with reference to FIG. 13. FIG. 13 is a perspective view of a board 2G according to Embodiment 7. Regarding points not specifically mentioned in the present embodiment, Embodiment 7 is similar to Embodiment 1.

The difference between the present embodiment and Embodiment 1 is that a switch 111 with a transmission line loss correction function and a signal distribution function is provided on the connection path between the IC 110 and the connector 11a.

The present embodiment has an effect that, when signals are transmitted from the IC 110 to the drive apparatus 10, transmission line losses are corrected by the equalizer of the switch 111, thereby making it possible to ensure the waveform quality required for high-speed transmission. Further, there is an effect that, even when the number of lanes of the connectors 102 and 103 is smaller than the total number of lanes of the drive apparatuses 10, it is possible to distribute signals to each drive by the switch 111.

### Embodiment 8

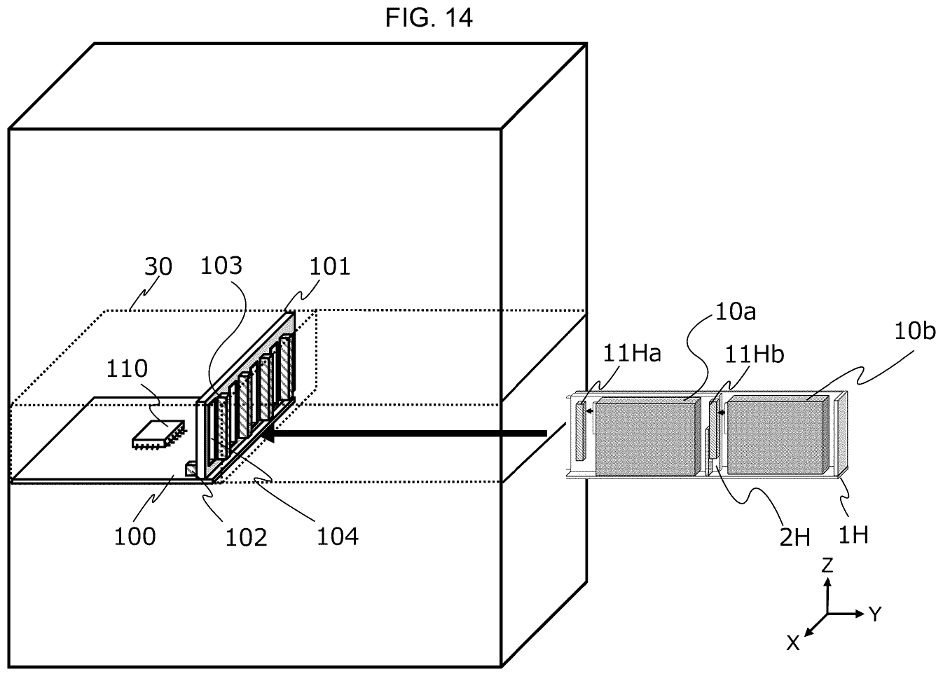

Embodiment 8 of the present invention is described with reference to FIG. 14. FIG. 14 is a perspective view of a board 2H and an adapter 1H according to Embodiment 8. Regarding points not specifically mentioned in the present embodiment, Embodiment 8 is similar to Embodiment 1.

In the present embodiment, compared to Embodiment 1, the shape of a connector 11H (11Ha or 11Hb) of the board 2H is identical to that of the connector 103 of the midplane 101. Thus, in the present embodiment, it is possible to directly connect the drive apparatus 10 to the connector 103. Further, it is possible to achieve drive expansion by replacing the single drive apparatus 10 with the board 2H having mounted thereon the plurality of drive apparatuses 10 without changing the storage housing accommodated in the rack 31.

### Embodiment 9

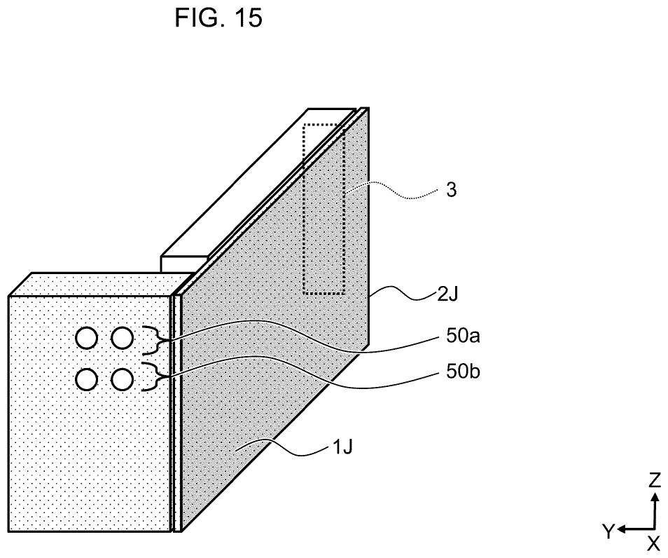

Embodiment 9 of the present invention is described with reference to FIG. 15. FIG. 15 is a perspective view of a board 2J and an adapter 1J according to Embodiment 9. Regarding points not specifically mentioned in the present embodiment, Embodiment 9 is similar to Embodiment 1.

The present embodiment is different from Embodiment 1 in that an access lamp 50 for each of the drive apparatuses 10 mounted on the board 2J for drive expansion is provided on the surface 62 on the positive side of the X-axis of the adapter 1J. For example, a lamp 50a lights up as an access lamp configured to notify the normal access status of the corresponding drive apparatus 10, while a lamp 50b lights up when notifying abnormalities of the corresponding drive apparatus 10. In the present embodiment, it is possible to grasp the state of the drive apparatus 10 when the adapter 1J is used.

The embodiments according to the present disclosure have been described above in detail, but the present disclosure is not limited to the embodiments described above and can be variously modified within the scope not departing from the gist thereof. For example, the embodiments described above have been described in detail to clearly describe the present invention, and the present invention is not necessarily limited to including all the described components. Further, regarding to some components of the embodiments described above, the addition, omission, or replacement involving other components is possible.

What is claimed is:

1. A storage apparatus comprising:
a plurality of drive apparatuses mounted;
a midplane provided vertically to an installation surface of the storage apparatus and provided with a plurality of first connectors arranged in parallel in a first direction parallel to the installation surface of the storage apparatus; and
a plurality of adapters on each of which a predetermined number of drive apparatuses among the plurality of drive apparatuses are mounted and which are arranged in parallel in the first direction and connected to the midplane through the plurality of respective first connectors in a second direction parallel to the installation surface and vertical to the first direction,
wherein each of the adapters includes
a board including
a connector connection portion connected to a corresponding one of the first connectors in the second direction, and
a plurality of second connectors electrically connected to the connector connection portion and connected to respective connectors of the predetermined number of drive apparatuses which are arranged in parallel in the second direction, in the second direction, and
a frame for mounting the predetermined number of drive apparatuses arranged in parallel in the second direction and the board to each of the adapters.

2. The storage apparatus according to claim 1,
wherein the frame includes, for a first drive apparatus and a second drive apparatus which are adjacent to each other among the predetermined number of drive apparatuses arranged in parallel in the second direction, between the first drive apparatus and one of the second connectors connected to the second drive apparatus, a stopper configured to restrict movement of the first drive apparatus in the second direction to prevent the first drive apparatus from coming into contact with the second drive apparatus.

3. The storage apparatus according to claim 1,
wherein the frame includes a slide rail configured to allow a corresponding one of the drive apparatuses to be moved in the second direction while being mounted on the frame.

4. The storage apparatus according to claim 1,
wherein the board has a notch portion or an opening portion, and
both surfaces in the first direction of each of the drive apparatuses are exposed from respective surfaces in the first direction of the board through one of the notch portion and the opening portion, in a state where a connector of each of the drive apparatuses is connected to a corresponding one of the second connectors.

5. The storage apparatus according to claim 4,
wherein the midplane has a through hole for allowing air to flow through the midplane, between the first connectors adjacent to each other.

6. The storage apparatus according to claim 1,
wherein, in each of the adapters, the connector connection portion is connected to the second connectors through a cable.

7. The storage apparatus according to claim 6,
wherein, in each of the adapters, one of the second connectors disposed at a location at a distance equal to or greater than a certain distance from the connector connection portion is connected to the connector connection portion through the cable, and one of the second connectors disposed at a location at a distance less than the certain distance from the connector connection portion is connected to the connector connection portion through the board.

8. The storage apparatus according to claim 6,
wherein each of the adapters includes a drive mounting portion for mounting a corresponding one of the drive apparatuses, and
the drive mounting portion rotates about a rotation axis in a third direction vertical to the first direction and the second direction in each of the adapters, thereby allowing the corresponding one of the drive apparatuses to be mounted and removed with respect to the drive mounting portion from a direction different from the second direction.

9. The storage apparatus according to claim 8,
wherein the drive mounting portion is connected to the connector connection portion by a cable with a folded portion folded in a bellows shape.

10. The storage apparatus according to claim 1, further comprising:
a switch with a transmission line loss correction function and a signal distribution function on a connection path between the connector connection portion and one of the second connectors.

11. The storage apparatus according to claim 1,
wherein the first connectors and the second connectors have identical shapes.

12. The storage apparatus according to claim 1, further comprising:
an access lamp for each of the predetermined number of drive apparatuses.
